(19) United States
(12) Patent Application Publication
(10) Pub. No.: US 2009/0315065 A1
(43) Pub. Date: Dec. 24, 2009

(54) NITRIDE SEMICONDUCTOR LIGHT-EMITTING DIODE AND METHOD OF MANUFACTURING THE SAME

(75) Inventor: Satoshi KOMADA, Osaka-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/487,204

(22) Filed: Jun. 18, 2009

(30) Foreign Application Priority Data
Jun. 19, 2008 (JP) 2008-160304

(51) Int. Cl. H01L 33/00

(52) U.S. Cl. 257/99; 438/22; 257/E33.064

(57) ABSTRACT

Provided are a nitride semiconductor light-emitting diode including an n-type nitride semiconductor layer, a p-type nitride semiconductor layer and a nitride semiconductor active layer set between the n-type nitride semiconductor layer and the p-type nitride semiconductor layer, and having a first transparent electrode layer containing indium tin oxide and a second transparent electrode layer containing tin oxide on a surface of the p-type nitride semiconductor layer opposite to the side provided with the nitride semiconductor active layer and a method of manufacturing the nitride semiconductor light-emitting diode.

This nonprovisional application is based on Japanese Patent Application No. 2008-160304 filed on Jun. 19, 2008 with the Japan Patent Office, the entire contents of which are hereby incorporated by reference.

### BACKGROUND OF THE INVENTION

1. Field of the Invention

The present invention relates to a nitride semiconductor light-emitting diode and a method of manufacturing the same, and more particularly, it relates to a nitride semiconductor light-emitting diode exhibiting high reliability also when the same is continuously driven by injecting a current in a high current density and a method of manufacturing the nitride semiconductor light-emitting diode.

2. Description of the Background Art

For example, Japanese Patent No. 3786898 discloses a nitride semiconductor light-emitting diode used for various applications including an optical display, a signal, a data storage, a communication device, an illuminator and medical appliances (refer to FIG. 1 and the paragraph [0008] of Japanese Patent No. 3786898, for example).

As shown in FIG. 14, the nitride semiconductor light-emitting diode described in Japanese Patent No. 3786898 is formed by successively stacking a GaN buffer layer 111, an n⁺-type GaN contact layer 112, an n-type AlGaN cladding layer 113, an InGaN light emitting layer 114 having a multiple quantum well (MQW) structure, a p-type AlGaN cladding layer 115, a p-type GaN contact layer 116 and an n⁺-type InGaN reverse tunneling layer 120 on a sapphire insulating substrate 110.

Both of a p-side ohmic electrode 117 formed to be in contact with the surface of n⁺-type InGaN reverse tunneling layer 120 and an n-side ohmic electrode 119 formed to be in contact with the surface of n⁺-type GaN contact layer 112 are made of indium tin oxide (ITO).

In the nitride semiconductor light-emitting diode described in Japanese Patent No. 3786898, p-side ohmic electrode 117 made of ITO implements ohmic contact with n+-type InGaN reverse tunneling layer 120, whereby high transmissivity can be ensured and light extraction efficiency is improved to consequently improve luminous efficiency as compared with a semitransparent metal electrode of Ni or Pd having a thickness of about 5 to 10 nm generally employed as a p-side ohmic electrode.

### SUMMARY OF THE INVENTION

A p-side ohmic electrode made of ITO, capable of attaining ohmic contact not only with an n-type nitride semiconductor layer but also with a p-type nitride semiconductor layer as described in the aforementioned Japanese Patent No. 3786898 and having high transmissivity for visible light, is useful as an electrode for a nitride semiconductor light-emitting diode.

If a nitride semiconductor light-emitting diode having such a p-side ohmic electrode made of ITO is continuously driven by injecting a current in a high current density, however, the p-side ohmic electrode made of ITO is disadvantageously blackened.

When a nitride semiconductor light-emitting diode is driven by injecting a current in a high current density, the quantity of light per light emitting area can be increased, and the nitride semiconductor light-emitting diode can be downsized as a result. Further, the cost for the nitride semiconductor light-emitting diode can also be reduced.

Therefore, awaited are a nitride semiconductor light-emitting diode exhibiting high reliability also when the same is continuously driven by injecting a current in a high current density and a method of manufacturing the nitride semiconductor light-emitting diode.

In consideration of the aforementioned circumstances, an object of the present invention is to provide a nitride semiconductor light-emitting diode exhibiting high reliability also when the same is continuously driven by injecting a current in a high current density and a method of manufacturing the nitride semiconductor light-emitting diode.

The present invention provides a nitride semiconductor light-emitting diode including an n-type nitride semiconductor layer, a p-type nitride semiconductor layer and a nitride semiconductor active layer set between the n-type nitride semiconductor layer and the p-type nitride semiconductor layer and having a first transparent electrode layer containing indium tin oxide and a second transparent electrode layer containing tin oxide on a surface of the p-type nitride semiconductor layer opposite to the side provided with the nitride semiconductor active layer.

In the nitride semiconductor light-emitting diode according to the present invention, the first transparent electrode layer is preferably set on a side closer to the p-type nitride semiconductor layer than the second transparent electrode layer.

In the nitride semiconductor light-emitting diode according to the present invention, the thickness of the first transparent electrode layer is preferably not more than 40 nm.

In the nitride semiconductor light-emitting diode according to the present invention, the second transparent electrode layer preferably contains antimony.

In the nitride semiconductor light-emitting diode according to the present invention, the second transparent electrode layer preferably contains fluorine.

In the nitride semiconductor light-emitting diode according to the present invention, the thickness of the second transparent electrode layer is preferably larger than the thickness of the first transparent electrode layer.

The present invention also provides a method of manufacturing the aforementioned nitride semiconductor light-emitting diode, including the step of forming the first transparent electrode layer in an atmosphere of at least 200° C.

The method of manufacturing the nitride semiconductor light-emitting diode according to the present invention preferably includes the step of forming the second transparent electrode layer in an atmosphere of at least 300° C.

The method of manufacturing the nitride semiconductor light-emitting diode according to the present invention preferably includes the step of forming the first transparent electrode layer in an oxygen atmosphere of at least 300° C. after forming the first transparent electrode layer.

The method of manufacturing the nitride semiconductor light-emitting diode according to the present invention preferably further includes the step of further heat-treating the first transparent electrode layer in a nitrogen atmosphere of at least 300° C. after the aforementioned heat treatment.

According to the present invention, a nitride semiconductor light-emitting diode exhibiting high reliability also when the same is continuously driven by injecting a current in a high current density and a method of manufacturing the nitride semiconductor light-emitting diode can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of an exemplary nitride semiconductor light-emitting diode according to the present invention;

FIG. 2 is a schematic sectional view of another exemplary nitride semiconductor light-emitting diode according to the present invention;

FIGS. 3 to 13 are schematic sectional views illustrating the steps of an exemplary method of manufacturing a nitride semiconductor light-emitting diode according to the present invention; and

FIG. 14 is a schematic sectional view of a conventional nitride semiconductor light-emitting diode.

### DESCRIPTION OF THE PREFERRED EMBODIMENTS

An embodiment of the present invention is now described. In the accompanying drawings, it is assumed that the same reference numerals denote portions identical or corresponding to each other.

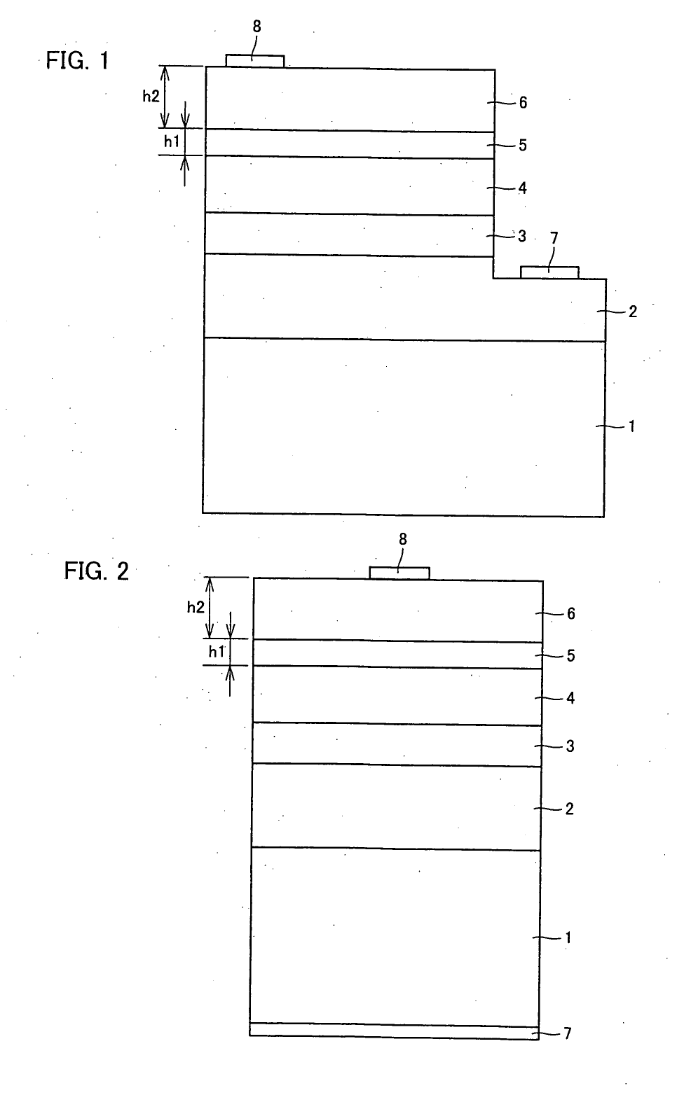

FIG. 1 is a schematic sectional view of an exemplary nitride semiconductor light-emitting diode according to the present invention. The nitride semiconductor light-emitting diode shown in FIG. 1 has a substrate 1, an n-type nitride semiconductor layer 2 formed on substrate 1, a nitride semiconductor active layer 3 formed on n-type nitride semiconductor layer 2, a p-type nitride semiconductor layer 4 formed on nitride semiconductor active layer 3, a first transparent electrode layer 5 formed on p-type nitride semiconductor layer 4 and a second transparent electrode layer 6 formed on first transparent electrode layer 5.

An n-side pad electrode 7 is formed on the surface of n-type nitride semiconductor layer 2 of the nitride semiconductor light-emitting diode, while a p-side pad electrode 8 is formed on the surface of second transparent electrode layer 6.

Substrate 1 can be formed by a well-known substrate of sapphire, silicon carbide or gallium nitride, for example.

N-type nitride semiconductor layer 2 can be made of a well-known n-type nitride semiconductor, for example, and can be formed by a single layer or a plurality of layers prepared by doping nitride semiconductor crystals expressed as Alₓ₁In_{y1}Ga_{z1}N (0≦x1≦1, 0≦y1≦1, 0≦z1≦1 and x1+y1+z1≠0) with an n-type impurity, for example. In the above formula, Al, In and Ga denote aluminum, indium and gallium respectively, and x1, y1 and z1 represent composition ratios of Al, In and Ga respectively. The n-type impurity can be prepared from silicon and/or germanium, for example.

Nitride semiconductor active layer 3 can be made of a well-known nitride semiconductor, for example, and can be formed by undoped nitride semiconductor crystals expressed as Alₓ₂In_{y2}Ga_{z2}N (0≦x2≦1, 0≦y2≦1, 0≦z2≦1 and x2+y2+z2≠0) or a single layer or a plurality of layers prepared by doping nitride semiconductor crystals expressed in this formula with at least either a p-type impurity or an n-type impurity, for example. In the above formula, Al, In and Ga denote aluminum, indium and gallium respectively, and x2, y2 and z2 represent composition ratios of Al, In and Ga respectively. Nitride semiconductor active layer 3 may have a well-known single quantum well (SQW) structure or a well-known multiple quantum well (MQW) structure.

P-type nitride semiconductor layer 4 can be made of a well-known p-type nitride semiconductor, for example, and can be formed by a single layer or a plurality of layers prepared by doping nitride semiconductor crystals expressed as Alₓ₃In_{y3}Ga_{z3}N (0≦x3≦1, 0≦y3≦1, 0≦z3≦1 and x3+y3+z3≠0) with a p-type impurity, for example. In the above formula, Al, In and Ga denote aluminum, indium and gallium respectively, and x3, y3 and z3 represent composition ratios of Al, In and Ga respectively. The p-type impurity can be prepared from magnesium and/or zinc, for example.

First transparent electrode layer 5 is formed by a transparent electrode layer containing indium tin oxide (ITO). First transparent electrode layer 5 is so formed by the transparent electrode layer containing ITO that contact resistance between first transparent electrode layer 5 and p-type nitride semiconductor layer 4 can be reduced.

The thickness h1 of first transparent electrode layer 5 is preferably not more than 40 nm, in order to improve reliability and luminous efficiency of the nitride semiconductor light-emitting diode. The lower limit of the thickness h1 of first transparent electrode layer 5, not particularly restricted, can be set to 5 nm, for example (i.e., the thickness h1 of first transparent electrode layer 5 can be set to at least 5 nm). An n-type nitride semiconductor layer capable of forming a tunnel junction with p-type nitride semiconductor layer 4 may be formed between first transparent electrode layer 5 and p-type nitride semiconductor layer 4.

Second transparent electrode layer 6 is formed by a transparent electrode layer containing tin oxide. This is because the inventor has found that tin oxide is superior in thermal stability and transmissiveness for light emitted from nitride semiconductor active layer 3 as compared with ITO. This is also because the inventor has found that high reliability can be attained without causing a problem such as blackening resulting from heat dissimilarly to the p-side ohmic electrode made of only ITO described in Japanese Patent No. 3786898 and luminous efficiency can be improved by improving thermal stability and light transmissiveness with second transparent electrode layer 6 containing tin oxide while ensuring ohmic contact between first transparent electrode layer 5 containing ITO and p-type nitride semiconductor layer 4 also when the nitride semiconductor light-emitting diode is continuously driven by injecting a current in a high current density.

Second transparent electrode layer 6 containing tin oxide preferably further contains at least either antimony or fluorine. When second transparent electrode layer 6 containing tin oxide further contains antimony and/or fluorine, resistivity of second transparent electrode layer 6 can be further reduced, and power efficiency of the nitride semiconductor light-emitting diode tends to be further increasable.

The thickness h2 of second transparent electrode layer 6 is preferably larger than the thickness hi of first transparent electrode layer 5. When the thickness h2 of second transparent electrode layer 6 is larger than the thickness h1 of first transparent electrode layer 5, the content of second transparent electrode layer 6 including tin oxide can be increased in a p-side ohmic electrode (a laminate of first and second transparent electrode layers 5 and 6) formed on the surface of p-type nitride semiconductor layer 4, whereby the reliability of the nitride semiconductor light-emitting diode can be further improved when the same is continuously driven by injecting a current in a high current density, and the luminous efficiency tends to be further increasable.

In consideration of the above, the content of antimony in second transparent electrode layer 6 is preferably at least 1×10⁻² mass %, more preferably at least 1'10⁻¹ mass % in overall second transparent electrode layer 6.

In consideration of the above, further, the content of fluorine in second transparent electrode layer 6 is preferably at least 1×10⁻² mass %, more preferably at least 1×10⁻¹ mass % in overall second transparent electrode layer 6.

N- and p-side pad electrodes 7 and 8 can be made of metals generally employed for n- and p-side pad electrodes of a nitride semiconductor light-emitting diode respectively, for example.

An exemplary method of manufacturing the nitride semiconductor light-emitting diode according to the present invention having the structure shown in FIG. 1 is now described.

First, n-type nitride semiconductor layer 2, nitride semiconductor active layer 3 and p-type nitride semiconductor layer 4 are crystal-grown on the surface of substrate 1 in this order by well-known MOCVD (metal organic chemical vapor deposition), for example.

Then, first transparent electrode layer 5 containing ITO is formed on the surface of p-type nitride semiconductor layer 4 by well-known EB (electron beam) deposition, for example.

Then, second transparent electrode layer 6 containing tin oxide is formed on the surface of first transparent electrode layer 5 by well-known EB deposition, for example.

Thereafter a wafer obtained by forming p-side pad electrode 8 on the surface of second transparent electrode layer 6 is partially etched from the side of second transparent electrode layer 6 until the surface of n-type nitride semiconductor layer 2 is exposed.

The nitride semiconductor light-emitting diode according to the present invention can be obtained by dividing the wafer into a plurality of portions after forming n-side pad electrode 7 on the surface of n-type nitride semiconductor layer 2 exposed by the etching.

In the above, first transparent electrode layer 5 containing ITO is preferably formed in an atmosphere of at least 200° C. When first transparent electrode layer 5 containing ITO is formed in the atmosphere of at least 200° C, transmissivity of first transparent electrode layer 5 with respect to the light emitted from nitride semiconductor active layer 3 is further improved and the luminous efficiency of the nitride semiconductor light-emitting diode tends to be further improved. In the present invention, it is assumed that the temperature denotes that of substrate 1.

In the above, second transparent electrode layer 6 containing tin oxide is preferably formed in an atmosphere of at least 300° C. When second transparent electrode layer 6 containing tin oxide is formed in the atmosphere of at least 300° C., the resistivity of second transparent electrode layer 6 containing tin oxide can be further reduced, and the power efficiency of the nitride semiconductor light-emitting diode tends to be further improvable.

In the above, first transparent electrode layer 5 is preferably heat-treated in an oxygen atmosphere of at least 300° C. after forming first transparent electrode layer 5 or after forming first and second transparent electrode layers 5 and 6. Thus, the contact resistance between first transparent electrode layer 5 containing ITO and p-type nitride semiconductor layer 4 tends to be further reducible.

Further, first transparent electrode layer 5 is preferably further heat-treated in a nitrogen atmosphere of at least 300° C. after the heat treatment in the aforementioned oxygen atmosphere. Thus, the resistivity of first transparent electrode layer 5 can be further reduced, whereby the power efficiency of the nitride semiconductor light-emitting diode tends to be further improvable.

FIG. 2 is a schematic sectional view of another exemplary nitride semiconductor light-emitting diode according to the present invention. The nitride semiconductor light-emitting diode shown in FIG. 2 is characterized in that a substrate I is formed by a conductive substrate and an n-side pad electrode 7 is formed on the rear surface of substrate 1.

According to the vertical electrode structure shown in FIG. 2, the nitride semiconductor light-emitting diode according to the present invention can be downsized. According to this structure, further, the number of nitride semiconductor light-emitting diodes obtained from a single wafer can be increased and no etching step is required for partially exposing the surface of an n-type nitride semiconductor layer 3 dissimilarly to the above, whereby production efficiency for the nitride semiconductor light-emitting diode can be improved. The remaining structure is similar to the above.

According to the present invention, as hereinabove described, a nitride semiconductor light-emitting diode exhibiting high reliability also when the same is continuously driven by injecting a current in a high current density and having high luminous efficiency can be obtained by forming the laminate of first transparent electrode layer 5 containing ITO and second transparent electrode layer 6 containing tin oxide as the p-side ohmic electrode in contact with p-type nitride semiconductor layer 4.

### EXAMPLES

### Example 1

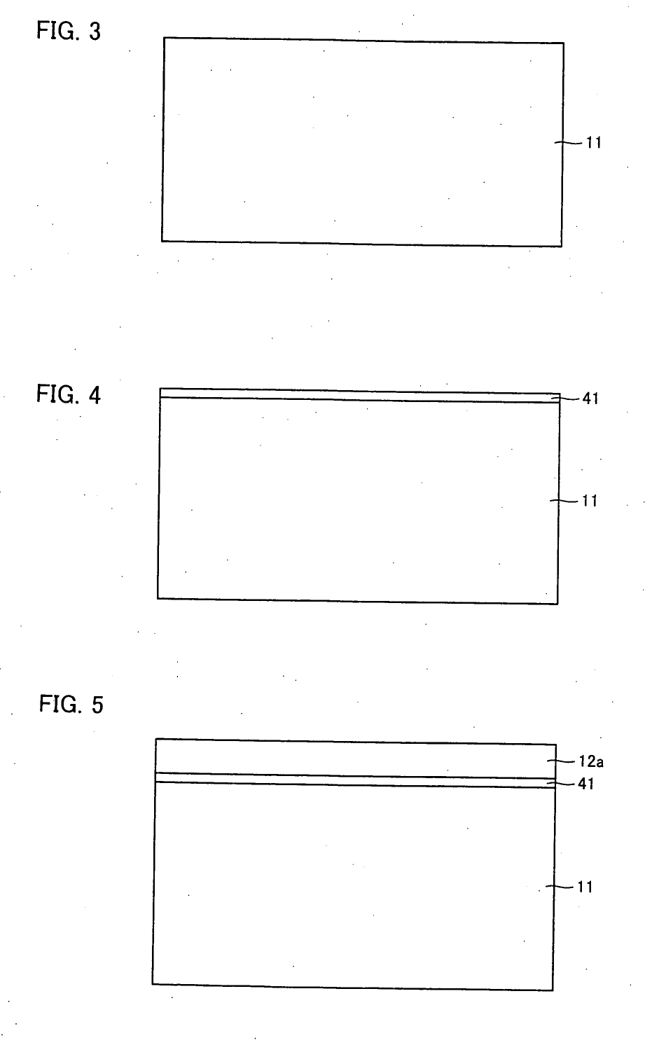

First, a sapphire substrate 11 having a structure shown in a schematic sectional view of FIG. 3 is prepared and set in a reactor of an MOCVD apparatus.

Then, the surface (C-plane) of sapphire substrate 11 is cleaned by increasing the temperature of sapphire substrate 11 to 1050° C. while feeding hydrogen into the reactor.

Then, a buffer layer 41 of GaN is formed on the surface (C-plane) of sapphire substrate 11 with a thickness of about 20 nm by MOCVD by reducing the temperature of sapphire substrate 11 to 510° C. and feeding hydrogen serving as a carrier gas and ammonia and TMG (trimethyl gallium) serving as source gasses into the reactor, as shown in a schematic sectional view of FIG. 4.

Then, an n-type nitride semiconductor underlayer 12a (carrier concentration: 1×10¹⁸/cm³) of GaN doped with Si (silicon) is formed on buffer layer 41 with a thickness of 6 μm by MOCVD by increasing the temperature of sapphire substrate 11 to 1050° C. and feeding hydrogen serving as a carrier gas, ammonia and TMG serving as source gases and silane serving as an impurity gas into the reactor, as shown in a schematic sectional view of FIG. 5.

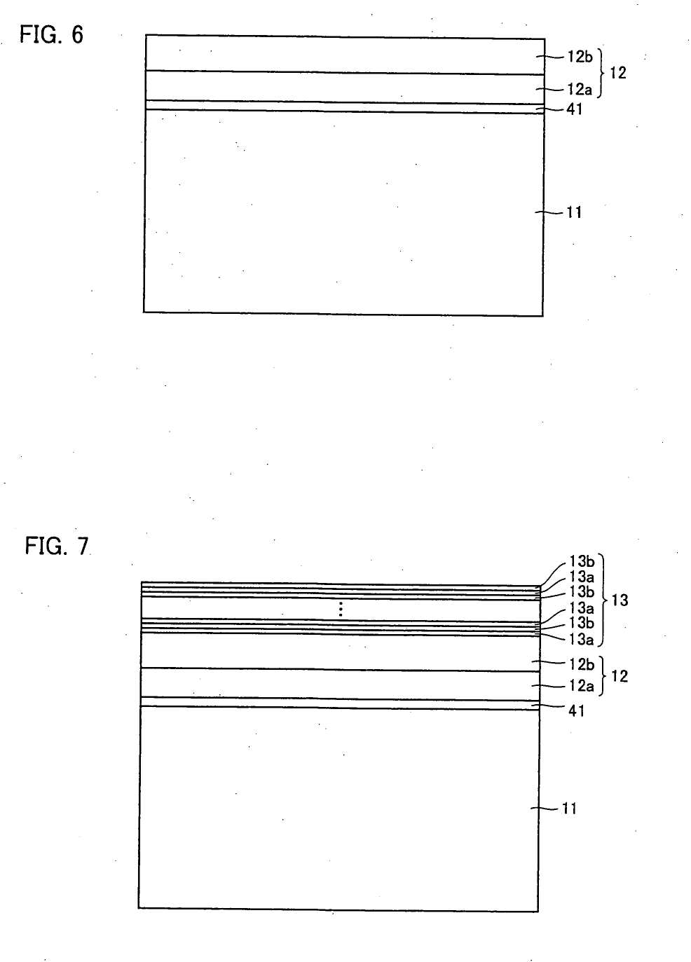

Then, an n-type nitride semiconductor contact layer 12b of GaN is formed on n-type nitride semiconductor underlayer 12a with a thickness of 0.5 μm by MOCVD similarly to n-type nitride semiconductor underlayer 12a, except that GaN is doped with Si so that the carrier concentration is 5×10¹⁸/cm³, as shown in a schematic sectional view of FIG. 6.

An n-type nitride semiconductor layer 12 consisting of a laminate of n-type nitride semiconductor underlayer 12a and n-type nitride semiconductor contact layer 12b is formed in the aforementioned manner.

Then, a nitride semiconductor active layer 13 having a multiple quantum well structure is formed by alternately growing six well layers 13a of In_{0.15}Ga_{0.85}N each having a thickness of 2.5 nm and six barrier layers 13b of GaN each having a thickness of 10 nm by reducing the temperature of sapphire substrate 11 to 700° C. and feeding nitrogen serving as a carrier gas and ammonia, TMG and TMI (trimethyl indium) serving as source gasses into the reactor, as shown in a schematic sectional view of FIG. 7. Needless to say, no TMI is fed into the reactor when barrier layers 13b of GaN are formed in the formation of nitride semiconductor active layer 13.

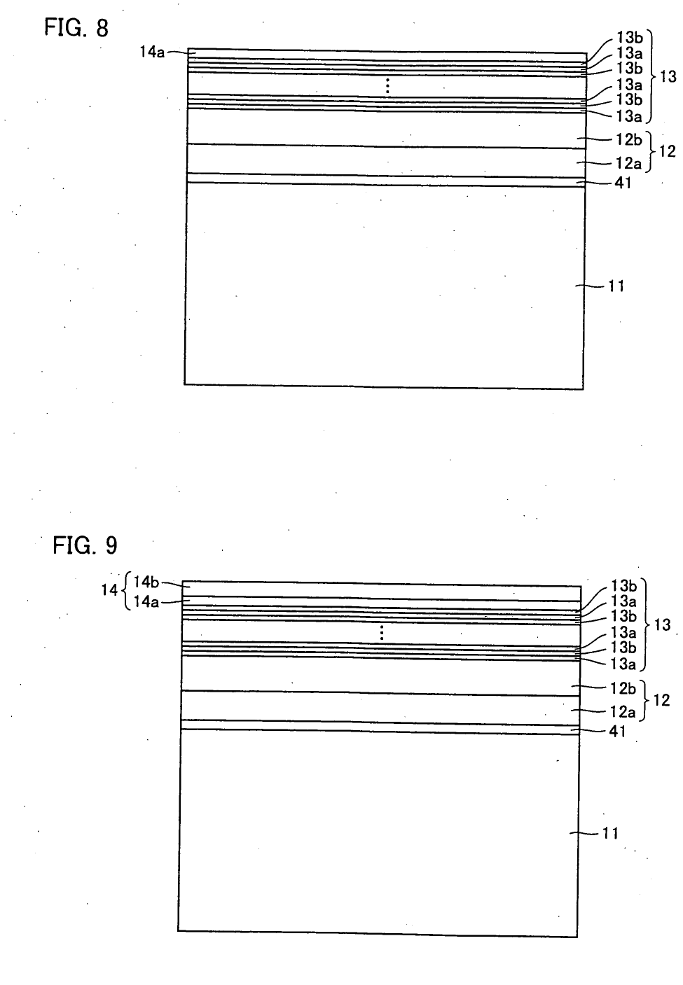

Then, a p-type nitride semiconductor cladding layer 14a of Al_{0.20}Ga_{0.80}N doped with Mg in a concentration of 1×10²⁰/cm³ is grown on nitride semiconductor active layer 13 with a thickness of about 20 nm by MOCVD by increasing the temperature of sapphire substrate 11 to 950° C. and feeding hydrogen serving as a carrier gas, ammonia, TMG and TMA (trimethyl aluminum) serving as source gasses and CP₂Mg (biscyclopentadienyl magnesium) serving as an impurity gas into the reactor, as shown in a schematic sectional view of FIG. 8.

Then, a p-type nitride semiconductor contact layer 14b of GaN doped with Mg in a concentration of 1×10²⁰/cm³ is formed on p-type nitride semiconductor cladding layer 14a with a thickness of 80 nm by MOCVD by keeping the temperature of sapphire substrate 11 at 950° C. and feeding hydrogen serving as a carrier gas, ammonia and TMG serving as source gasses and CP₂Mg serving as an impurity gas into the reactor, as shown in a schematic sectional view of FIG. 9.

A p-type nitride semiconductor layer 14 consisting of a laminate of p-type nitride semiconductor cladding layer 14a and p-type nitride semiconductor contact layer 14b is formed in the aforementioned manner.

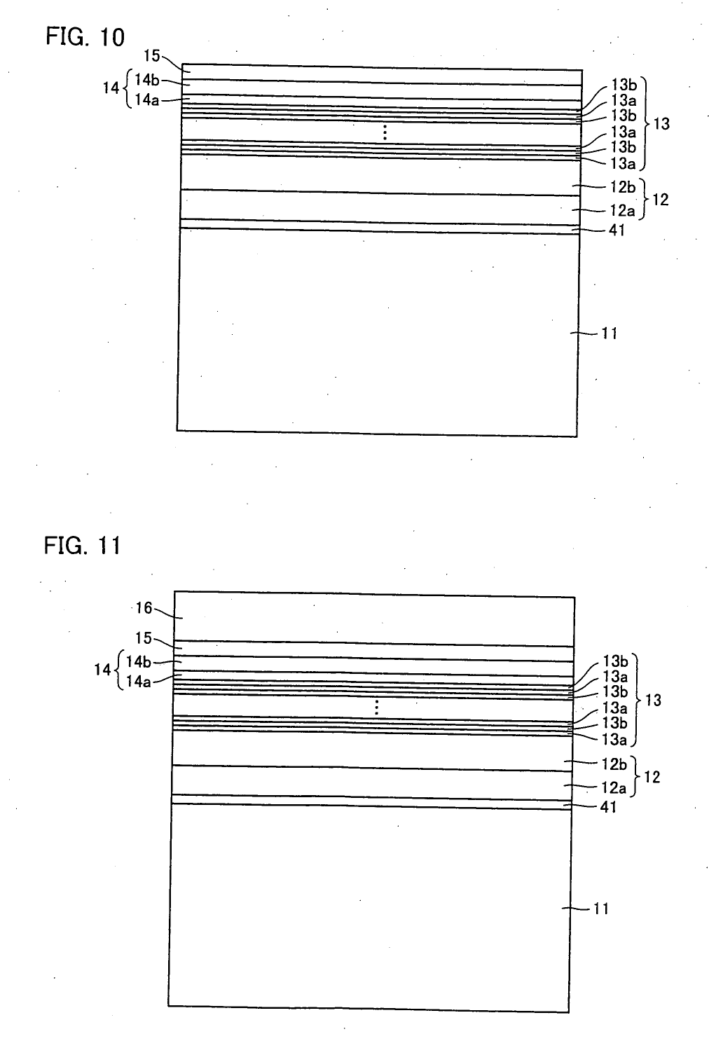

Then, a wafer obtained by forming p-type nitride semiconductor layer 14 is taken out of the reactor, and a first transparent electrode layer 15 of ITO is formed on p-type nitride semiconductor layer 14 constituting the uppermost layer of the wafer with a thickness of 20 nm by EB deposition in an oxygen atmosphere of 300° C., as shown in a schematic sectional view of FIG. 10.

Then, a second transparent electrode layer 16 of tin oxide is formed on the surface of first transparent electrode layer 15 with a thickness of 250 nm by EB deposition at 550° C., as shown in a schematic sectional view of FIG. 11.

Then, first transparent electrode layer 15 is heated by heat-treating the wafer provided with second transparent electrode layer 16 in an oxygen atmosphere of 600° C. for 10 minutes and thereafter heat-treating the same in a nitrogen atmosphere of 600° C. for one minute.

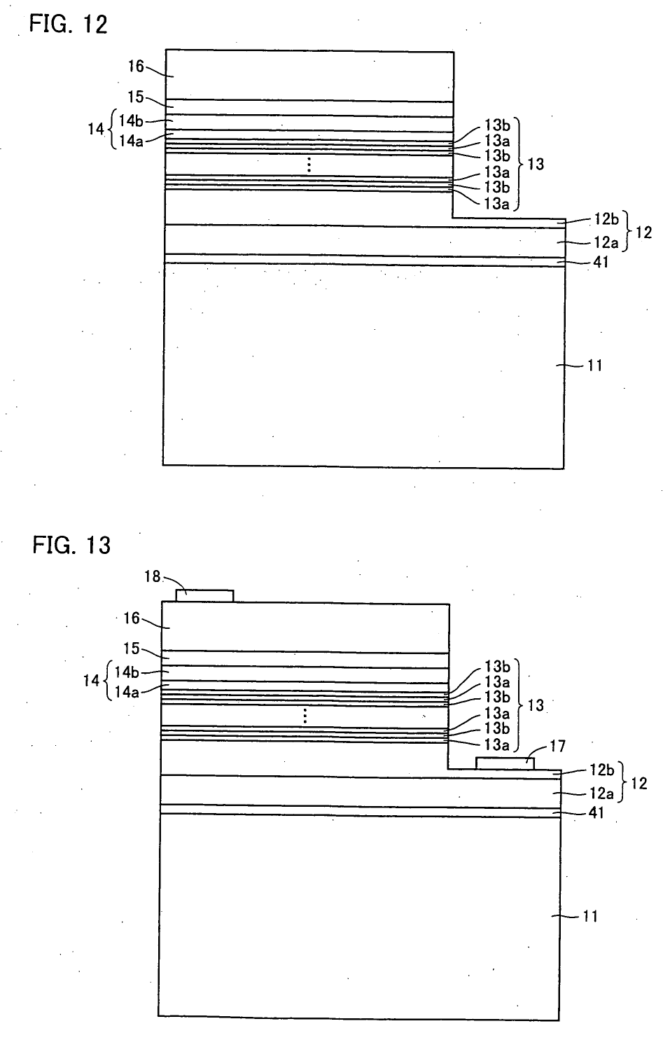

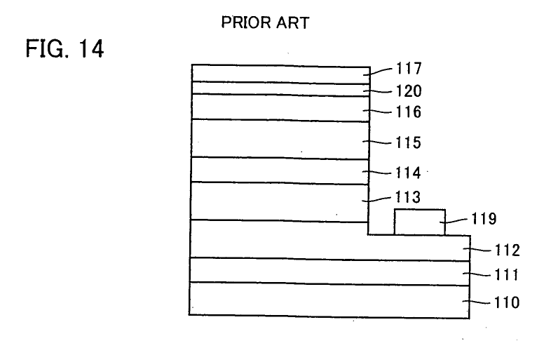

Then, a mask patterned to have an opening in a prescribed shape is formed on the surface of second transparent electrode layer 16 and the wafer is etched from the side of second transparent electrode layer 16 in an RME (reactive ion etching) apparatus to partially expose the surface of n-type nitride semiconductor contact layer 12b, as shown in a schematic sectional view of FIG. 12.

Then, a p-side pad electrode 18 and an n-side pad electrode 17 containing Ti and Al are formed on prescribed positions of the surfaces of second transparent electrode layer 16 and n-type nitride semiconductor contact layer 12b respectively, as shown in a schematic sectional view of FIG. 13. Thereafter a nitride semiconductor light-emitting diode according to Example 1 is obtained by dividing the wafer provided with n- and p-side pad electrodes 17 and 18.

The nitride semiconductor light-emitting diode according to Example 1 exhibits high reliability also when the same is continuously driven by injecting a current in a high current density of at least 50 A/cm², for example, without thermal deterioration of a p-side ohmic electrode consisting of a laminate of first and second transparent electrode layers 15 and 16.

Further, the p-side ohmic electrode consisting of the laminate of first and second transparent electrode layers 15 and 16 has higher transmissivity for light emitted from nitride semiconductor active layer 13 as compared with a nitride semiconductor light-emitting diode according to comparative example 1 described later, whereby light extraction efficiency can be improved, and luminous efficiency can also be improved as a result.

### Example 2

According to Example 2, a nitride semiconductor light-emitting diode is prepared similarly to Example 1, except for conditions for forming a second transparent electrode layer 16. In other words, the nitride semiconductor light-emitting diode according to Example 2 is obtained by forming a first transparent electrode layer 15 and thereafter forming second transparent electrode layer 16 of antimony and tin oxide with a thickness of 250 nm by performing reactive deposition at 350° C. with a deposition source prepared from an alloy of tin and antimony.

The nitride semiconductor light-emitting diode according to Example 2 exhibits high reliability also when the same is continuously driven by injecting a current in a high current density without thermal deterioration of a p-side ohmic electrode consisting of a laminate of first and second transparent electrode layers 15 and 16, similarly to the nitride semiconductor light-emitting diode according to Example 1.

Further, resistivity of second transparent electrode layer 16 can be more reduced as compared with that in the nitride semiconductor light-emitting diode according to Example 1, whereby an operating voltage can be reduced, and power efficiency can be improved.

Also when second transparent electrode layer 16 of the nitride semiconductor light-emitting diode according to Example 2 is replaced with a second transparent electrode layer 16 made of tin oxide and fluorine or a second transparent electrode layer 16 made of tin oxide, antimony and fluorine, effects similar to those of the nitride semiconductor light-emitting diode according to Example 2 can be attained.

### Example 3

According to Example 3, a nitride semiconductor light-emitting diode is prepared similarly to Example 1, except for conditions for forming a first transparent electrode layer 15. In other words, the nitride semiconductor light-emitting diode according to Example 3 is obtained by forming first transparent electrode layer 15 of ITO on the surface of a p-type nitride semiconductor layer 14 with a thickness of 20 nm by EB deposition in an atmosphere of an arbitrary temperature (temperature of a sapphire substrate 11) in the range of room temperature to 300° C.

In the nitride semiconductor light-emitting diode according to Example 3, transmissivity of first transparent electrode layer 15 made of ITO is increased and high luminous efficiency can be implemented when first transparent electrode layer 15 is formed in such an atmosphere that the temperature of sapphire substrate 11 is at least 200° C.

### Example 4

According to Example 4, a nitride semiconductor light-emitting diode is prepared similarly to Example 1, except for conditions for forming a second transparent electrode layer 16. In other words, the nitride semiconductor light-emitting diode according to Example 4 is obtained by forming second transparent electrode layer 16 of tin oxide on the surface of a first transparent electrode layer 15 with a thickness of 250 nm by EB deposition in an atmosphere of an arbitrary temperature (temperature of a sapphire substrate 11) in the range of room temperature to 550° C.

In the nitride semiconductor light-emitting diode according to Example 4, resistivity of second transparent electrode layer 16 made of tin oxide is reduced and high power efficiency can be implemented when second transparent electrode layer 16 is formed in such an atmosphere that the temperature of sapphire substrate 11 is at least 300° C.

### Comparative Example 1

According to comparative example 1, a nitride semiconductor light-emitting diode is prepared similarly to Example 1, except that a first transparent electrode layer 15 of ITO is formed on the surface of a p-type nitride semiconductor layer 14 with a thickness of 250 nm by EB deposition in such an atmosphere that the temperature of a sapphire substrate 11 is 300° C. and no second transparent electrode layer 16 is thereafter formed.

In the nitride semiconductor light-emitting diode according to comparative example 1, therefore, a transparent conductive film provided on the surface of p-type nitride semiconductor layer 14 consists of only first transparent electrode layer 15 made of ITO.

According to the present invention, a nitride semiconductor light-emitting diode exhibiting high reliability also when the same is continuously driven by injecting a current in a high current density and a method of manufacturing the nitride semiconductor light-emitting diode can be provided.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light-emitting diode including:
an n-type nitride semiconductor layer;
a p-type nitride semiconductor layer; and
a nitride semiconductor active layer set between said n-type nitride semiconductor layer and said p-type nitride semiconductor layer, and having:
a first transparent electrode layer containing indium tin oxide, and
a second transparent electrode layer containing tin oxide
on a surface of said p-type nitride semiconductor layer opposite to the side provided with said nitride semiconductor active layer.

2. The nitride semiconductor light-emitting diode according to claim 1, wherein
said first transparent electrode layer is set on a side closer to said p-type nitride semiconductor layer than said second transparent electrode layer.

3. The nitride semiconductor light-emitting diode according to claim 1, wherein
the thickness of said first transparent electrode layer is not more than 40 nm.

4. The nitride semiconductor light-emitting diode according to claim 1, wherein
said second transparent electrode layer contains antimony.

5. The nitride semiconductor light-emitting diode according to claim 1, wherein
said second transparent electrode layer contains fluorine.

6. The nitride semiconductor light-emitting diode according to claim 1, wherein
the thickness of said second transparent electrode layer is larger than the thickness of said first transparent electrode layer.

7. A method of manufacturing the nitride semiconductor light-emitting diode as recited in claim 1, including the step of forming said first transparent electrode layer in an atmosphere of at least 200° C.

8. The method of manufacturing the nitride semiconductor light-emitting diode according to claim 7, including the step of forming said second transparent electrode layer in an atmosphere of at least 300° C.

9. The method of manufacturing the nitride semiconductor light-emitting diode according to claim 7, including the step of heat-treating said first transparent electrode layer in an oxygen atmosphere of at least 300° C. after forming said first transparent electrode layer.

10. The method of manufacturing the nitride semiconductor light-emitting diode according to claim 9, including the step of further heat-treating said first transparent electrode layer in a nitrogen atmosphere of at least 300° C. after said heat treatment.
